(19) United States
(12) Patent Application Publication
(10) Pub. No.: US 2006/0286756 A1
(43) Pub. Date: Dec. 21, 2006

(54) SEMICONDUCTOR PROCESS AND METHOD FOR REDUCING PARASITIC CAPACITANCE

(76) Inventor: Chien-Wei Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,325

(22) Filed: Jun. 20, 2005

(51) Int. Cl. H01L 21/336

(52) U.S. Cl. 438/299; 438/592; 438/595

(57) ABSTRACT

A semiconductor processes is described. A substrate having trench isolation structures and dummy trench isolation structures thereon is provided. Gate structures and dummy gate structures are simultaneously formed on the substrate. Spacers are formed on the sidewalls of the gate structures and the dummy gate structures. A patterned blocking layer is formed covering the dummy gate structures and the substrate between the dummy trench isolation structures. Thereafter, a salicide layer is formed on exposed surfaces of the gate structures and the substrate.

### BACKGROUND OF THE INVENTION

1. Field of the Invention

The present invention relates to a semiconductor process. More particularly, the present invention relates to a semiconductor process capable of reducing parasitic capacitance of the product and improving the reliability of the same, and to a method for reducing parasitic capacitance.

2. Description of the Related Art

As the IC industry advances rapidly, device dimensions are always decreased to achieve higher integration, so is the distance between adjacent devices. However, when the distance is decreased to a certain extent, the interference between adjacent devices is severe. Therefore, methods for fabricating semiconductor devices of high integration degree with reduced dimensions but good electrical properties are desired.

One important solution to the issue is the use of trench isolation structures. In current shallow trench isolation (STI) process, chemical mechanical polishing (CMP) is utilized instead of traditional dry etching-back to improve the smoothness of wafer surface, simplify the process and greatly increases the yield and usable area on a wafer. However, there are still some problems about CMP, mainly due to that the polishing rate varies with the size and density of the patterns, which is caused by that the local polishing pressure on denser (sparser) patterns is smaller (larger). Therefore, the wafer areas having low pattern density are usually over-polished, so that the smoothness of the wafer surface is reduced lowering the reliability of later processed. For example, the isolation material filled in a wider STI structure is easily over-polished to produce a dishing effect.

Analogously, after the fabrication of gate structures, the reliability of subsequent lithography and/or etching processes is usually lowered due to the non-uniformity in density of the gate patterns.

To solve the above problems, additional dummy patterns are usually formed in an STI process or a gate process to improve the uniformity in pattern density.

However, incorporation of dummy patterns also causes some problems in later processes. For example, in a later salicide process, a silicide layer will be formed not only on the gates and the substrate beside each gate, but also on the dummy gates and the substrate between the dummy trench isolation structures. Hence, the parasitic capacitance of the circuitry is increased lowering the speed and reliability of the same.

### SUMMARY OF THE INVENTION

In view of the foregoing, this invention provides a semiconductor process capable of reducing the parasitic capacitance of the circuitry.

Another object of this invention is to provide a method for reducing parasitic capacitance of the circuitry and thereby improving the speed and reliability of the same.

The semiconductor process of this invention is described below. A substrate having trench isolation structures and dummy trench isolation structures thereon is provided. A gate structure is formed on the substrate between two adjacent trench isolation structures, and dummy gate structures are formed on the substrate at the same time. A spacer is formed on the sidewall of each of the gate structures and the dummy gate structures. A patterned blocking layer is then formed covering the dummy gate structures and the substrate between the dummy trench isolation structures. Then, a salicide layer is formed on exposed surfaces of the gate structures and the substrate.

The blocking layer in the above process may be formed with chemical vapor deposition (CVD), and the material thereof may be silicon oxide or silicon nitride.

Moreover, at least one of the dummy gate structures may be formed on a dummy trench isolation structure or on a portion of the substrate between two adjacent dummy trench isolation structures; or be formed covering the substrate between two adjacent dummy trench isolation structures, covering the substrate between two adjacent dummy trench isolation structures as well as a portion of the two dummy trench isolation structures, or covering a portion of the substrate between two adjacent dummy trench isolation structures and a portion of the two dummy trench isolation structures.

In one preferred embodiment of the above semiconductor process, an extra doping process is conducted, and a patterned mask layer is formed covering the dummy gate structures and the substrate between the dummy trench isolation structures before the doping process. The material of the mask layer is silicon nitride, for example.

In addition, the material of the above salicide layer may be a silicide of a refractory metal, wherein the refractory metal is, for example, titanium (Ti), tungsten (W), platinum (Pt), cobalt (Co) or nickel (Ni).

The method for reducing parasitic capacitance of this invention is applied to a substrate that has trench isolation structures and dummy trench isolation structures, a gate structure on the substrate between two adjacent trench isolation structures and dummy gate structures thereon. In the method, a patterned blocking layer is formed covering the dummy gate structures and the substrate between the dummy trench isolation structures before the salicide process. The blocking layer may be formed through CVD, and the material thereof may be silicon oxide or silicon nitride.

In one preferred embodiment, the parasitic capacitance of the circuitry is further reduced by forming a patterned mask layer covering the dummy gate structures and the substrate between the dummy trench isolation structures before a predetermined doping process that is included in the same semiconductor process including the salicide process.

Another method for reducing parasitic capacitance of this invention is applied to a substrate that has, or will have, trench isolation structures and dummy trench isolation structures, a gate structure on the substrate between two adjacent trench isolation structures and dummy gate structures between the dummy trench isolation structures thereon. In the method, a patterned mask layer is formed covering the substrate between the dummy trench isolation structures, or between predetermined regions of the dummy trench isolation structures in cases where the dummy trench isolation structures have not been formed, before a doping process. The patterned mask layer also covers the dummy gate structures if the dummy gate structures have been formed.

In the above method, the material of the mask layer may be silicon nitride, and the doping process may include a substrate doping process, a well doping process, a gate-conductor doping process, or a light or heavy source/drain doping process.

Since a patterned blocking layer is formed covering the dummy gate structures and the substrate between the dummy trench isolation structures before the salicide process, the silicide layer will not be formed thereon, so that the parasitic capacitance of the circuitry is smaller as compared with the prior art. Similarly, by forming a patterned mask layer covering the non-device regions before a doping process, the non-device regions will not be doped in the doping process, so that the parasitic capacitance of the circuitry is smaller as compared with the prior art.

It is to be understood that both the foregoing general description and the following detailed description are exemplary, and are intended to provide further explanation of the invention as claimed.

### BRIEF DESCRIPTION OF THE DRAWINGS

FIGS. 1-4 schematically illustrate, in a cross-sectional view, the process flow of a semiconductor process according to a preferred embodiment of this invention.

### DESCRIPTION OF THE PREFERRED EMBODIMENTS

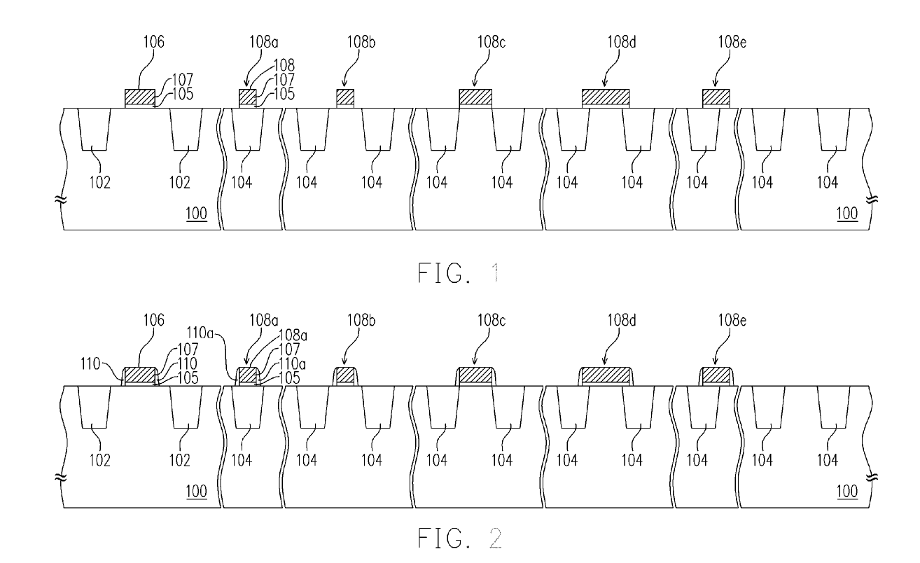

Referring to FIG. 1, trench isolation structures 102 are formed on the substrate 100 possibly with the following steps. A pad oxide layer and a hard mask layer (not shown) are formed and then patterned through lithography and etching to form trenches therein, and then the substrate 100 is etched using the patterned hard mask layer as a mask to form trenches therein. An insulating layer is formed over the substrate 100 through CVD to fill up the trenches, wherein the insulating layer may be a silicon oxide layer. A CMP process is then performed to remove a portion of the insulating layer with the hard mask layer as a polishing stop layer. Wet etching is conducted to remove the pad oxide and the hard mask layer to complete fabrication of the trench isolation structures 102.

To prevent a dishing effect in regions of lower pattern density in CMP, dummy trench isolation structures 104 are formed on the substrate 100 simultaneously with the trench isolation structures 102 to improve the uniformity of pattern density.

Thereafter, a gate structure 106 is formed on the substrate 100 between two adjacent trench isolation structures 102. The gate structure 106 includes a dielectric layer 105 and a conductor 107 on the dielectric layer 105, wherein the material of the dielectric layer 105 may be silicon oxide and that of the conductor 107 may be poly-Si.

Similarly, to improve the uniformity of the gate pattern density, dummy gate structures 108a/b/c/d/e as illustrated in FIG. 2 are formed over the substrate 100 together with the gate structures 106, wherein each dummy gate structure 108 also includes a dielectric layer 105 and a conductor 107 on the dielectric layer 105.

Generally, the dummy gate structures 108 may be disposed in various manners. For example, the dummy gate structure 108a is formed on a dummy trench isolation structure 104, so that the substrate 100 between the dummy trench isolation structure 104 and the adjacent one is completely exposed. The dummy gate structure 108b is formed on a portion of the substrate 100 between two adjacent dummy trench isolation structures 104, so that the substrate 100 between the two dummy trench isolation structures 104 is partially exposed. The dummy gate structure 108c is formed on the substrate 100 between two adjacent dummy trench isolation structures 104, substantially covering the same without overlapping with the two dummy trench isolation structures 104. The dummy gate structure 108d is formed covering the substrate 100 between two adjacent dummy trench isolation structures 104 as well as a portion of the two dummy trench isolation structures 104. The dummy gate structure 108e is formed covering a portion of the substrate 100 between two adjacent dummy trench isolation structures and a portion of the two dummy trench isolation structures 104, wherein the substrate 100 between the two dummy isolation structures 104 is partially exposed.

Referring to FIG. 2, spacers 110 and 110a are formed on the sidewall of the gate structure 106 and that of each dummy gate structure 108, respectively, wherein the material of the spacers 110 and 110a may be silicon nitride. The spacers 110 and 110a can be formed by depositing a conformal insulating layer over the substrate 100 and then etching the insulating layer anisotropically to remove portions of the same.

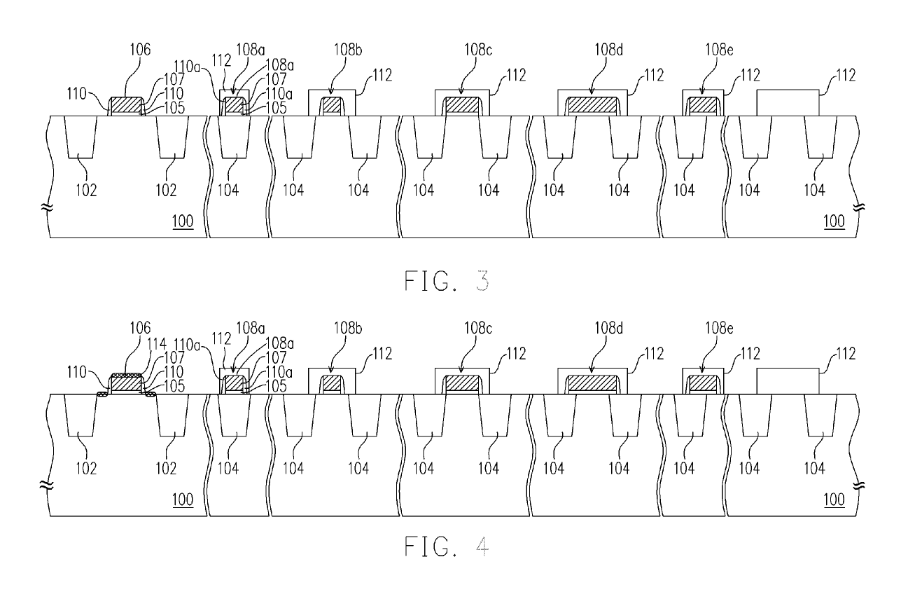

Referring to FIG. 3, a patterned blocking layer 112 is formed over the substrate 100 covering the dummy gate structures 108 and the substrate 100 between the dummy trench isolation structures 104. The blocking layer 112 is formed through CVD, for example, and the material thereof may be silicon oxide or silicon nitride. Particularly, the patterned blocking layer 112 can be a modified salicide blocking (SAB) layer that is originally designed to block some devices like DRAM cells in a salicide process in the prior art. The patterned blocking layer 112 differs from a conventional SAB layer in that the former further covers the dummy gate structures 108 and the substrate 100 between the dummy trench isolation structures 104. In such cases, formation of the patterned blocking layer 112 does not require an additional step, so that the process will not be complicated and the manufacturing cost will not be raised.

Referring to FIG. 4, a salicide process is conducted to form a metal silicide layer 114 on the exposed surfaces of the gate structure 106 and the substrate 100. The material of the metal silicide layer 114 may be a silicide of a refractory metal like Ti, W, Pt, Co or Ni. Taking a nickel salicide process as an example, a layer of nickel is firstly sputtered onto the substrate 100, and then a rapid thermal annealing (RTA) process is conducted to react nickel with the underlying silicon atoms to form a nickel silicide layer. A selective wet-etching step is then performed to remove the unreacted nickel layer, and then another RTA process is conducted to convert the nickel silicide to a low-resistance phase.

Since the dummy gate structures 108 and the substrate 100 between the dummy trench isolation structures 104 are covered by the patterned blocking layer 112 in the salicide process, no metal silicide is formed thereon. Hence, the parasitic capacitance of the circuitry can be lowered as compared with the prior art.

In another preferred embodiment of this invention, a doping step is performed during or prior to the process of FIGS. 1-4. In this embodiment, a patterned mask layer is formed covering the non-device regions as in the case of FIG. 3 before the doping step, wherein the material of the mask layer is, for example, silicon nitride or other suitable material. If the doping process is conducted before the STI process, the patterned mask layer is formed covering the substrate between the predetermined regions of the dummy trench isolation structures. If the doping process is conducted before the gate process but after the STI process, the patterned mask layer is formed covering the substrate between the dummy trench isolation structures. If the doping process is conducted after the gate process, the patterned mask layer covers the substrate between the dummy trench isolation structures as well as the dummy gate structures. Since the semiconductor materials in the non-device regions are not doped for being masked by the patterned mask layer, the parasitic capacitance of the circuitry is further reduced as compared with the prior art.

Examples of the doping process possibly conducted in this invention include: a substrate doping process that is done before formation of gate structures to increase the conductivity of the substrate, a well doping process for forming a well in the substrate, a gate-conductor doping process for adjusting the electrical properties of the gates, a light source/drain (S/D) doping process for forming S/D extensions in a substrate that may use a gate structure as a mask, and a heavy doping process for forming S/D regions in a substrate that may use a gate structure and a spacer on the sidewall of the gate structure as a mask. By forming a patterned mask layer covering the non-device regions before any of the above doping processes, the non-device regions are not doped in the doping process, so that the parasitic capacitance can be lowered as compared with the prior art.

In summary, by forming a patterned blocking layer before a salicide process to prevent metal silicide from being formed on the dummy gate structures and the substrate between the dummy trench isolation structures and/or forming a patterned mask layer before a doping process to prevent the non-device regions from being doped, the present invention is capable of reducing the parasitic capacitance of the circuitry. Particularly, the patterned blocking layer can be a modified SAB layer that also covers the dummy pattern regions, so that the whole process is not complicated as compared with the prior art.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A semiconductor process, comprising:
providing a substrate having a plurality of trench isolation structures and dummy trench isolation structures thereon;
forming a gate structure on the substrate between two adjacent trench isolation structures as well as a plurality of dummy gate structures on the substrate;
forming a spacer on a sidewall of each of the gate structures and the dummy gate structures;
forming a patterned blocking layer covering the dummy gate structures and the substrate between the dummy trench isolation structures; and
forming a salicide layer on exposed surfaces of the gate structures and the substrate.

2. The semiconductor process of claim 1, wherein the step of forming the blocking layer comprises a CVD process.

3. The semiconductor process of claim 1, wherein the blocking layer comprises silicon oxide or silicon nitride.

4. The semiconductor process of claim 1, wherein at least one of the dummy gate structures is formed on a dummy trench isolation structure.

5. The semiconductor process of claim 1, wherein at least one of the dummy gate structures is formed on a portion of the substrate between two adjacent dummy trench isolation structures.

6. The semiconductor process of claim 1, wherein at least one of the dummy gate structures is formed covering the substrate between two adjacent dummy trench isolation structures.

7. The semiconductor process of claim 1, wherein at least one of the dummy gate structures is formed covering the substrate between two adjacent dummy trench isolation structures as well as a portion of the two dummy trench isolation structures.

8. The semiconductor process of claim 1, wherein at least one of the dummy gate structures is formed covering a portion of the substrate between two adjacent dummy trench isolation structures and a portion of the two dummy trench isolation structures.

9. The semiconductor process of claim 1, further comprising:
forming a patterned mask layer covering the dummy gate structures and the substrate between the dummy trench isolation structures; and
performing a doping process with the patterned mask layer as a mask.

10. The semiconductor process of claim 9, wherein the mask layer comprises silicon nitride.

11. The semiconductor process of claim 1, wherein the salicide layer comprises a silicide of a refractory metal.

12. The semiconductor process of claim 11, wherein the refractory metal is selected from the group consisting of titanium, tungsten, platinum, cobalt and nickel.

13. A method for reducing parasitic capacitance, applied to a substrate that has a plurality of trench isolation structures and dummy trench isolation structures, a gate structure on the substrate between two adjacent trench isolation structures and a plurality of dummy gate structures thereon, and comprising:
forming a patterned blocking layer covering the dummy gate structures and the substrate between the dummy trench isolation structures before a salicide process.

14. The method of claim 13, wherein the step of forming the blocking layer comprises a CVD process.

15. The method of claim 13, wherein the blocking layer comprises silicon oxide or silicon nitride.

16. The method of claim 13, further comprising:
forming a patterned mask layer covering the dummy gate structures and the substrate between the dummy trench isolation structures before a predetermined doping process that is included in a semiconductor process including the salicide process.

17. The method of claim 13, wherein the salicide layer comprises a silicide of a refractory metal.

18. The method of claim 17, wherein the refractory metal is selected from the group consisting of titanium, tungsten, platinum, cobalt and nickel.

19. A method for reducing parasitic capacitance, applied to a substrate that has, or will have, a plurality of trench isolation structures and dummy trench isolation structures, a gate structure on the substrate between two adjacent trench isolation structures and a plurality of dummy gate structures between the dummy trench isolation structures thereon, and comprising:
forming a patterned mask layer covering the substrate between the dummy trench isolation structures or between predetermined regions of the dummy trench isolation structures before a doping process, wherein the patterned mask layer also covers the dummy gate structures if the dummy gate structures have been formed.

20. The method of claim 19, wherein the mask layer comprises silicon nitride.

21. The method of claim 19, wherein the doping process includes a substrate doping process, a well doping process, a gate-conductor doping process, or a light or heavy source/drain doping process.
